(19) United States
(12) Patent Application Publication
(10) Pub. No.: US 2026/0016502 A1
(43) Pub. Date: Jan. 15, 2026

(54) TIP LENGTH CALIBRATION DEVICE AND PROBE SYSTEM INCLUDING THE SAME, TESTED SEMICONDUCTOR DEVICE AND METHOD FOR PRODUCING THE SAME, METHOD FOR TIP LENGTH CALIBRATION, AND METHOD FOR TESTING UNPACKAGED SEMICONDUCTOR DEVICE

(71) Applicant: MPI CORPORATION, Zhubei City (TW)

(72) Inventors: TING-AN YEN, Zhubei City (TW); Po-Yl Ting, Zhubei City (TW); Yu-Hsun Hsu, Zhubei City (TW); Sebastian Giessmann, Zhubei City (TW)

(21) Appl. No.: 19/221,632

(22) Filed: May 29, 2025

Related U.S. Application Data
(60) Provisional application No. 63/671,412, filed on Jul. 15, 2024.

(51) Int. Cl. G01R 1/067; G01R 31/28; G01R 35/00

(52) U.S. Cl. CPC G01R 1/06738; G01R 1/06794; G01R 31/2887; G01R 35/005

(57) ABSTRACT

A tip length calibration device, a probe system including the same, a tested semiconductor device, a method for producing the same, a method for tip length calibration, and a method for testing an unpackaged semiconductor device. The tip length calibration device includes a base, a position adjusting mechanism, and a target detection module. The position adjusting mechanism and the target detection module are disposed on the base. The position adjusting mechanism is configured to move the probe assembly to a sensing region, and the target detection module is configured to determine whether a tip portion of the probe assembly is present in the sensing region, such that a calibrated tip length can be acquired.

### CROSS-REFERENCE TO RELATED PATENT APPLICATION

This application claims the benefit of priority to the U.S. Provisional Patent Application Ser. No. 63/671,412 filed on Jul. 15, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a device and method for calibrating a probe assembly and applications of the calibrated probe assembly, and more particularly to a tip length calibration device, a probe system including the same, a tested semiconductor device, a method for producing the same, a method for tip length calibration, and a method for testing an unpackaged semiconductor device.

### BACKGROUND OF THE DISCLOSURE

Probe systems can be used to test the operation and performance of a device under test (DUT), such as a semiconductor, a solid state device, an electrical device, an optical device, or an optoelectronic device. For example, in a probe system, an optical fiber is configured to interface with the DUT, so as to transmit optical signals to the DUT or receive optical signals from the DUT via a fiber tip thereof. In such an example, a capacitive distance sensor can be used in combination with the optical fiber to determine a separation distance between the DUT and the optical fiber.

More specifically, in a probe system, after an optical fiber is installed onto a probe arm of the probe assembly, it is crucial for precise measurement to determine a correct “fiber length,” which is a distance from a fiber tip to a lower surface (sensor surface) of a capacitive distance sensor.

However, the capacitive distance sensor has a limited sensing range (e.g., a range from 500 μm to 900 μm). If the fiber length is too long or too short after initial installation, causing the fiber tip to be outside of the sensing range, the optical fiber would need to be reassembled or adjusted for tip position by using an image capturing device and a mirror that cooperate with each other. Since the mirror is used to confirm the position of the fiber tip, the fiber tip needs to come into slight contact with a physical surface to acquire an accurate fiber length. However, such manner of operation makes the fiber tip prone to collision damage during an adjustment process due to improper operation. Additionally, in the adjustment process, the probe assembly needs to be installed on a probe positioner, and external force applied to the probe assembly may cause damage to the probe positioner during installation.

Therefore, it is essential to improve the adjustment process for determining a fiber length, so as to reduce the need for repeated adjustments on the probe positioner. As a result, the number of times that the probe positioner needs to be used for installation or adjustments can be reduced, thereby minimizing the risk of the probe positioner being damaged.

### SUMMARY OF THE DISCLOSURE

In response to the above-referenced technical inadequacies, the present disclosure provides a tip length calibration device, a probe system including the same, a tested semiconductor device, a method for producing the same, a method for tip length calibration, and a method for testing an unpackaged semiconductor device.

In order to solve the above-mentioned problems, one of the technical aspects adopted by the present disclosure is to provide a tip length calibration device of a probe assembly, which includes a base, a position adjusting mechanism, and a target detection module. The base has a reference surface corresponding in position to a sensing surface of a non-contact sensor of the probe assembly. The target detection module is disposed on the base and configured to determine whether a tip portion of the probe assembly is present in a sensing region next to the reference surface. The position adjusting mechanism is disposed on the base and configured to move the probe assembly toward the base, so as to have the tip portion be present in the sensing region and acquire a tip length that is a vertical distance between a tip end of the tip portion and the sensing surface.

In one of the possible or preferred embodiments, the position adjusting mechanism includes a first movement assembly that is connected to a retaining component of the probe assembly, so as to drive the probe assembly to move along a first direction perpendicular to the reference surface.

In one of the possible or preferred embodiments, the position adjusting mechanism includes a mounting plate for mounting the retaining component on the first movement assembly.

In one of the possible or preferred embodiments, the position adjusting mechanism includes a second movement assembly and a third movement assembly. The second movement assembly is disposed on the base. The third movement assembly is disposed on the second movement assembly. The first movement assembly is disposed on the third movement assembly. Furthermore, the second movement assembly is drivingly connected to the third movement assembly, so as to move the probe assembly along a second direction perpendicular to the first direction via the third movement assembly. The third movement assembly is drivingly connected to the first movement assembly, so as to move the probe assembly along a third direction perpendicular to the second direction via the first movement assembly.

In one of the possible or preferred embodiments, the retaining component includes a first end portion, a second end portion, and a middle portion extending from the first end portion to the second end portion, and the first end portion is immovably fixed to mounting plate. Furthermore, the probe assembly includes a probe that has the tip portion. The probe and the non-contact sensor are retained on the second end portion, such that the tip portion extends beyond a plane where the sensing surface is located.

In one of the possible or preferred embodiments, the target detection module includes a light emitter and a light receiver that are respectively located at two sides of the sensing region and opposite to each other. The light emitter is configured to emit a light beam to be detected. The light receiver is configured to receive the light beam, so as to provide a detection value. Furthermore, when the tip portion blocks the light beam and results in a change in detection value, the tip portion is determined as being present in the sensing region, and a distance between the sensing surface and the reference surface measured by the non-contact sensor is the tip length.

In one of the possible or preferred embodiments, the target detection module includes a light adjusting component that is located on a transmission path of the light beam and configured to allow a plane where the light beam is located to be coplanar with the reference surface.

In one of the possible or preferred embodiments, the light adjusting component includes a light-permeable window that corresponds in position to a light emitting surface of the light emitter. Furthermore, the light adjusting component is configured to be adjusted for adjusting a height of the light-permeable window.

In one of the possible or preferred embodiments, the base includes a calibration platform that is at least partially disposed between the light emitter and the light receiver and provided with the reference surface, and the light adjusting component is disposed between the light emitter and the calibration platform.

In one of the possible or preferred embodiments, the target detection module includes an amplifier that is electrically connected to the light receiver, so as to receive a sensing signal from the light receiver and amplify the sensing signal to generate a readout signal corresponding to the detection value.

In order to solve the above-mentioned problems, another one of the technical aspects adopted by the present disclosure is to provide a method for tip length calibration of a probe assembly, which includes: providing the tip length calibration device as described above; mounting the probe assembly on the position adjusting mechanism; and performing a tip length calibration operation on the probe assembly. Furthermore, the tip length calibration operation includes: controlling an operation of the position adjusting mechanism to move the probe assembly toward the base; determining whether a tip portion of the probe assembly is present in a sensing region next to the reference surface by the target detection module; terminating the operation of the position adjusting mechanism when the tip portion is present in the sensing region; and acquiring a vertical distance between a tip end of the tip portion and the sensing surface.

In one of the possible or preferred embodiments, before the step of performing the tip length calibration operation, the method further includes performing a pre-calibration operation. Furthermore, the pre-calibration operation includes: providing another probe assembly that includes another probe and another non-contact sensor, in which the another probe has another tip portion with a known tip length; controlling an operation of the position adjusting mechanism to move the another probe assembly along the horizontal direction and acquiring a relative distance variation between a sensing surface of the another non-contact sensor and the reference surface by the another non-contact sensor; determining whether the relative distance variation is less than a predetermined value; controlling another operation of the position adjusting mechanism to move the another probe assembly toward the base when the relative distance variation is less than the predetermined value; determining whether the another tip portion is present in the sensing region by the target detection module; and determining whether a detection value of the another non-contact sensor is equal to the known tip length when the another tip portion is present in the sensing region, and if not, adjusting a height position of the light-permeable window until the detection value of the another non-contact sensor is equal to the known tip length.

In order to solve the above-mentioned problems, yet another one of the technical aspects adopted by the present disclosure is to provide a probe system, which includes a chuck, a probe assembly, a motorized positioner, and the tip length calibration device as described above. The chuck has a support surface to support a substrate, and the substrate includes a device under test (DUT). The probe assembly is configured to test the DUT. The tip length calibration device is configured to perform a tip length calibration operation on the probe assembly. The motorized positioner is configured to position the probe assembly relative to the substrate.

In one of the possible or preferred embodiments, the probe assembly includes a retaining component, a probe, and a non-contact sensor. The retaining component is connected to the motorized positioner. The probe is retained on the retaining component to provide a test signal to the DUT or receive a resultant signal from the DUT, and has a tip portion. The non-contact sensor is retained on the retaining component to measure a distance from the substrate to the sensing surface. The non-contact sensor has a sensing surface, and the tip portion extends beyond a plane where the sensing surface is located.

In one of the possible or preferred embodiments, the probe is an optical fiber.

In order to solve the above-mentioned problems, still another one of the technical aspects adopted by the present disclosure is to provide a tested semiconductor device, which includes an unpackaged semiconductor device that has at least one optical coupler to be interfaced with the probe assembly in the probe system as described.

In order to solve the above-mentioned problems, still another one of the technical aspects adopted by the present disclosure is to provide a method for testing an unpackaged semiconductor device, which includes: using the tip length calibration device to perform a tip length calibration operation on a probe assembly, so as to acquire a calibrated tip length of the probe assembly; and using the probe assembly to test an unpackaged semiconductor device, wherein the probe assembly includes an optical fiber to transmit optical signals to the unpackaged semiconductor device and/or receive optical signals from the unpackaged semiconductor device.

In order to solve the above-mentioned problems, still another one of the technical aspects adopted by the present disclosure is to provide a method for producing a tested semiconductor device, which includes: using the tip length calibration device to perform a tip length calibration operation on a probe assembly, so as to acquire a calibrated tip length of the probe assembly; and using the probe assembly to test an unpackaged semiconductor device, wherein the probe assembly includes an optical fiber to transmit optical signals to the unpackaged semiconductor device and/or receive optical signals from the unpackaged semiconductor device.

In conclusion, the tip length calibration device provided by the present disclosure can be used to perform a tip length calibration operation on a probe assembly, so as to make the probe assembly have a calibrated tip length without direct contact with an object such as a calibration chuck. Therefore, a tip portion of the probe assembly can be prevented from being damaged. Furthermore, the tip length calibration device can save time and effort for tip length calibration.

Furthermore, the probe assembly that has undergone the tip length calibration operation can be used in a probe system for testing an unpackaged semiconductor device, thereby producing a tested semiconductor device.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a tip length calibration device of the present disclosure;

FIG. 2 is a schematic planar view of the tip length calibration device of the present disclosure;

FIG. 3 is a partial schematic perspective view of the tip length calibration device of the present disclosure;

FIG. 4A and FIG. 4B are partial schematic planar views of the tip length calibration device of the present disclosure;

FIG. 5 a schematic view of a probe system of the present disclosure;

FIG. 6 a schematic view of a tested semiconductor device of the present disclosure;

FIG. 7 a flowchart of a method for tip length calibration of the present disclosure;

FIG. 8 a flowchart of step S106 of the method for tip length calibration of the present disclosure;

FIG. 9 a flowchart of step S104 of the method for tip length calibration of the present disclosure; and

FIG. 10 a flowchart of a method for testing an unpackaged semiconductor device of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

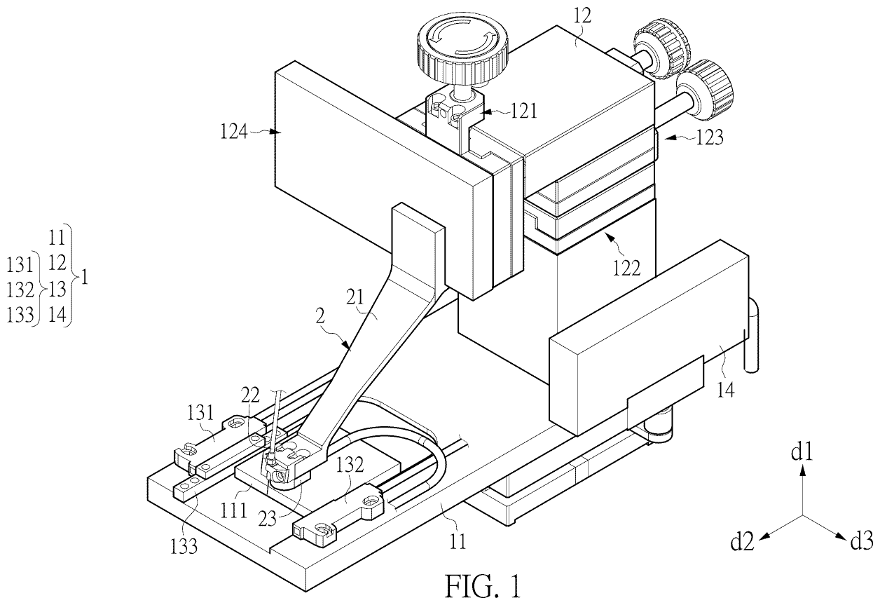

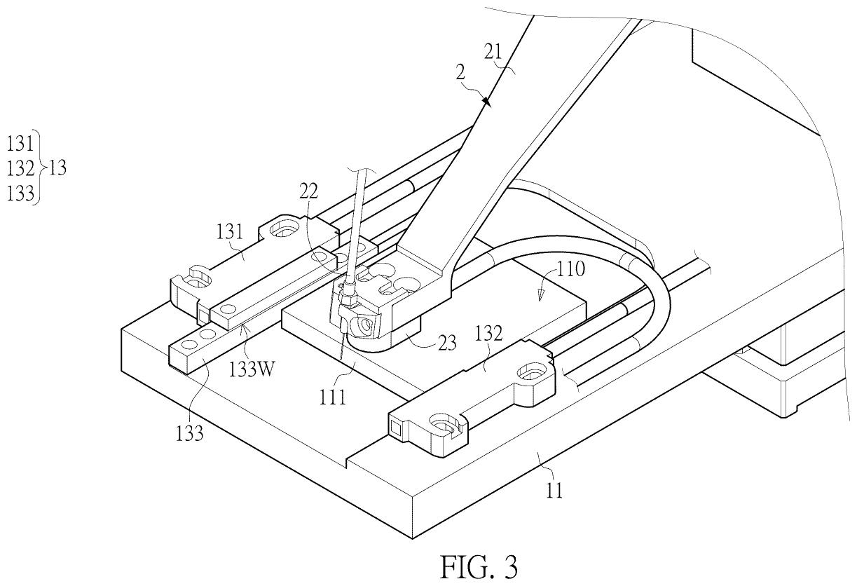

Referring to FIG. 1 to FIG. 4A, a first embodiment of the present disclosure provides a tip length calibration device 1 for tip length calibration of a probe assembly 2. The tip length calibration device 1 mainly includes a base 11, a position adjusting mechanism 12, and a target detection module 13.

In use, the probe assembly 2 is mounted on and operatively connected to the tip length calibration device 1, such that a tip length calibration operation can be performed on the probe assembly 2 by the tip length calibration device 1. Accordingly, a calibrated tip length (i.e., a fiber-to-sensor distance) of the probe assembly 2 can be acquired without direct contact with an object such as a calibration chuck, thereby preventing a tip portion 221 of the probe assembly 2 from being damaged. The probe assembly 2 that has undergone the tip length calibration operation can be used in a probe system for testing an unpackaged semiconductor device, thereby producing a tested semiconductor device.

In the first embodiment, the probe assembly 2 includes a retaining component 21, a probe 22, and a non-contact sensor 23. The retaining component 21 is mounted on the tip length calibration device 1. The probe 22 and the non-contact sensor 23 are retained on the retaining component 21 and adjacent to each other, and a tip portion 221 of the probe 22 extends beyond a plane where a sensing surface 230 of the non-contact sensor 23 is located. The probe 22 can be an optical fiber, and the non-contact sensor 23 can be a capacitive sensor for non-contact measurement of displacement, distance and position, but are not limited thereto. Furthermore, in the tip length calibration device 1, the position adjusting mechanism 12 and the target detection module 13 are disposed on the base 11.

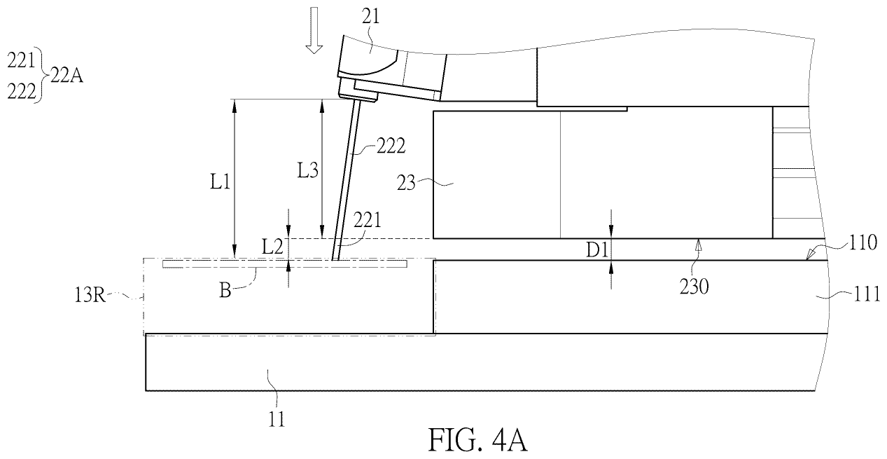

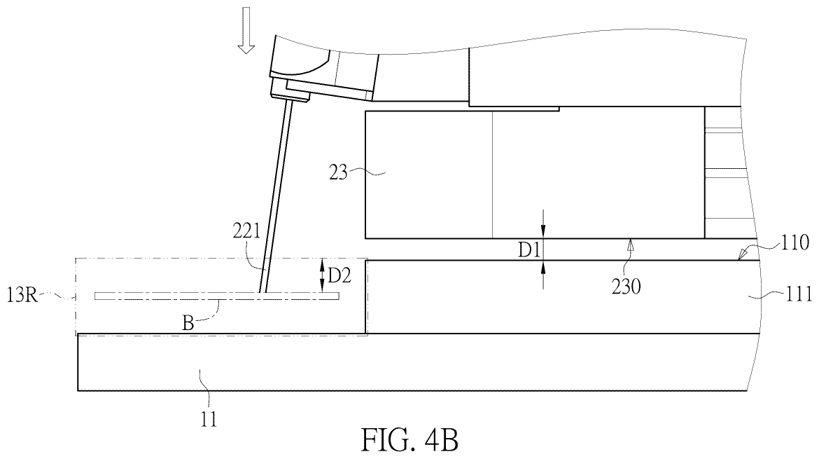

As shown in FIG. 4A, the probe 22 includes an active part 22A extending beyond the bottom of the retaining component 21. The active part 22A includes the tip portion 221 and a body portion 222 between the tip portion 221 and the retaining component 21. In practice, the tip portion 221 is connected to the body portion 222 and configured to interface with a device under test (DUT). A vertical length L1 of the active part 22A is the sum of a vertical length L2 of the tip portion 221 and a vertical length L3 of the body portion 222.

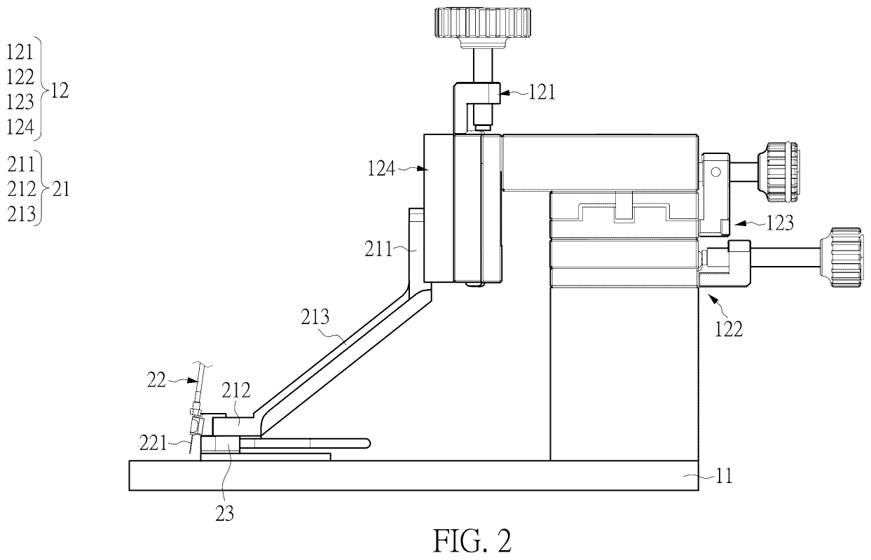

Reference is made to FIG. 1, FIG. 2 and FIG. 4A. In the tip length calibration operation, the base 11 has a reference surface 110 corresponding in position to the sensing surface 230 of the non-contact sensor 23. The target detection module 13 is configured to determine whether the tip portion 221 of the probe assembly 2 is present in a sensing region 13R next to the reference surface 110. The position adjusting mechanism 12 is configured to move the probe assembly 2 toward the base 11, so as to have the tip portion 221 be present in the sensing region 13R. Accordingly, a tip length that is a distance DI from the reference surface 110 to the sensing surface 230 can be acquired by the non-contact sensor 23. In other words, the tip length refers to a distance that the tip end of the tip portion 221 extends below the bottom boundary of the sensing surface 230 of the non-contact sensor 23. In the first embodiment, when the tip portion 221 is determined as being present in the sensing region 13R, a plane where a tip end of the tip portion 221 is located is coplanar with the sensing surface 230. Thus, the distance D1 is equal to a vertical length between a tip end of the tip portion 221 and the sensing surface 230, but the present disclosure is not limited thereto.

More specifically, the base 11 includes a calibration platform 111 that is provided with the reference surface 110. The position adjusting mechanism 12 includes a first movement assembly 121 that is connected to the retaining component 21. Accordingly, by controlling an operation of the first movement assembly 121, the probe assembly 2 can be moved up and down along a first direction d1 (e.g., the Z direction) perpendicular to the reference surface 110 of the base 11. In order to allow movements of the probe assembly 2 in the horizontal direction, the position adjusting mechanism 12 further includes a second movement assembly 122 and a third movement assembly 123, the second movement assembly 122 is disposed on the base 11. The third movement assembly 123 is disposed on the second movement assembly 122, and the first movement assembly 121 is disposed on the third movement assembly 123.

Furthermore, the second movement assembly 122 is drivingly connected to the third movement assembly 123, and the third movement assembly 123 is drivingly connected to the first movement assembly 121. Accordingly, by controlling an operation of the second movement assembly 122, the probe assembly 2 can be moved along a second direction d2 (e.g., the X direction) perpendicular to the first direction d1 along with the third movement assembly 123. By controlling an operation of the third movement assembly 123, the probe assembly 2 can be moved along a third direction d3 (e.g., the Y direction) perpendicular to the second direction d2 along with the first movement assembly 121.

In practice, the position adjusting mechanism 12 includes a mounting plate 124 for mounting the retaining component 21 on the first movement assembly 121. The first movement assembly 121, the second movement assembly 122, and the third movement assembly 123 are each a linear stage, but are not limited thereto. The linear stage can include a base portion, a stage portion slidably engaged with the base portion, and a drive shaft disposed between and interconnecting the base portion and the stage portion. The rotation of the drive shaft drives the stage portion to move on the base portion.

As shown in FIG. 2, the retaining component 21 can be a retaining arm that includes a first end portion 211, a second end portion 212, and a middle portion 213 extending from the first end portion 211 to the second end portion 212. The first end portion 211 is immovably fixed to mounting plate 124, and the probe 22 and the non-contact sensor 23 are retained on the second end portion 212.

Reference is made to FIG. 2 to FIG. 4A. The target detection module 13 includes a light emitter 131 and a light receiver 132 that are respectively located at two sides of the sensing region 13R and opposite to each other. The light emitter 131 is configured to emit a light beam B having a predetermined wavelength, and a beam plane (a plane where the light beam B is located) is coplanar with the reference surface 110. The light receiver 132 is configured to receive the light beam B, so as to provide a detection value. Furthermore, the probe assembly 2 can be moved toward the base 11 in the tip length calibration operation, and when the tip portion 221 blocks the light beam B and results in a change in detection value, the tip portion 221 is determined as being present in the sensing region 13R, as shown in FIG. 4A. Accordingly, a distance D1 from the reference surface 110 to the sensing surface 230 can be acquired by the non-contact sensor 23 to serve as a tip length, which is equal to a vertical distance between a tip end of the tip portion 221 and the sensing surface 230.

Referring to FIG. 4B, the tip length calibration operation can be performed under the condition that the beam plane is not coplanar with the reference surface 110. For example, the beam plane is lower than the reference surface 110. Specifically, in the tip length calibration operation, when the tip portion 221 blocks the light beam B and results in a change in detection value, the sum of the distance D1 acquired by the non-contact sensor 23 and a vertical distance D2 between the beam plane and the reference surface 110 is determined as a tip length. In practice, the vertical distance D2 can be measured in advance. In other words, the tip length refers to a distance that the tip end of the tip portion 221 extends below the bottom boundary of the sensing surface 230 of the non-contact sensor 23.

In practice, the target detection module 13 can further include a light adjusting component 133 for adjusting the distribution of the light beam B. The light adjusting component 133 is located on a transmission path of the light beam B and configured to allow a plane where the light beam B is located to be coplanar with the reference surface 110, so as to ensure that the distance D1 is equal to the tip length. In addition, the target detection module 13 includes an amplifier 134 that is electrically connected to the light receiver 132. Accordingly, the amplifier 134 can receive a sensing signal from the light receiver 132 and amplify the sensing signal to generate a readout signal corresponding to the detection value.

More specifically, the calibration platform 111 is at least partially disposed between the light emitter 131 and the light receiver 132, and the light adjusting component 133 is disposed between the light emitter 131 and the calibration platform 111. Furthermore, the light adjusting component 133 includes a light-permeable window 133W that corresponds in position to a light emitting surface of the light emitter 131, and is configured to be adjusted for adjusting a height of the light-permeable window 133W.

### Second Embodiment

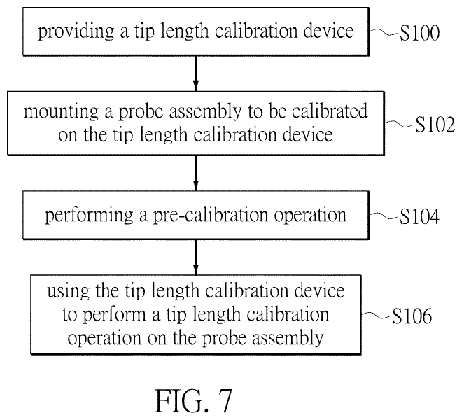

Referring to FIG. 7, a second embodiment of the present disclosure provides a method for tip length calibration of a probe assembly, which can be implemented by using the tip length calibration device as described in the first embodiment. Accordingly, a tip length (i.e., a fiber-to-sensor distance) of the probe assembly can be acquired. The probe assembly that has undergone the tip length calibration can be used in a probe system for testing an unpackaged semiconductor device, thereby producing a tested semiconductor device.

As shown in FIG. 7, the method includes: step S100, providing a tip length calibration device; step S102, mounting a probe assembly to be calibrated on the tip length calibration device; and step S106, using the tip length calibration device to perform a tip length calibration operation on the probe assembly.

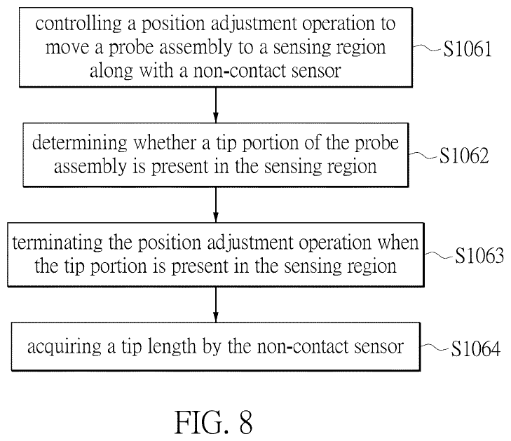

Reference is made to FIG. 8. In step S106, the tip length calibration operation includes: step S1061, controlling a position adjustment operation to move a probe assembly to a sensing region along with a non-contact sensor; step S1062, determining whether a tip portion of the probe assembly is present in the sensing region; step S1063, terminating the position adjustment operation when the tip portion is present in the sensing region; and step S1064, acquiring a tip length by the non-contact sensor.

Reference is made to FIG. 1 to FIG. 4A. In step S102, the probe assembly 2 is mounted on and operatively connected to a position adjusting mechanism 12 of the tip length calibration device 1. In step S1061, a downward movement of the probe assembly 2 to a sensing region 13R can be caused by the position adjusting mechanism 12. In step S1062, a target detection module 13 of the tip length calibration device 1 is used to determine where the tip portion 221 is in the sensing region 13R. In step S1063, when the tip portion 221 is detected as being present in the sensing region 13R, the operation of position adjusting mechanism 12 is terminated. In step S1064, a distance DI from a reference surface 110 to a sensing surface 230 can be measured by the non-contact sensor 23 to serve as the tip length.

In the second embodiment, the method can further include a step of performing a pre-calibration operation (step S104) to calibrate the reference height position of target detection, before the step of performing the tip length calibration operation (step S106).

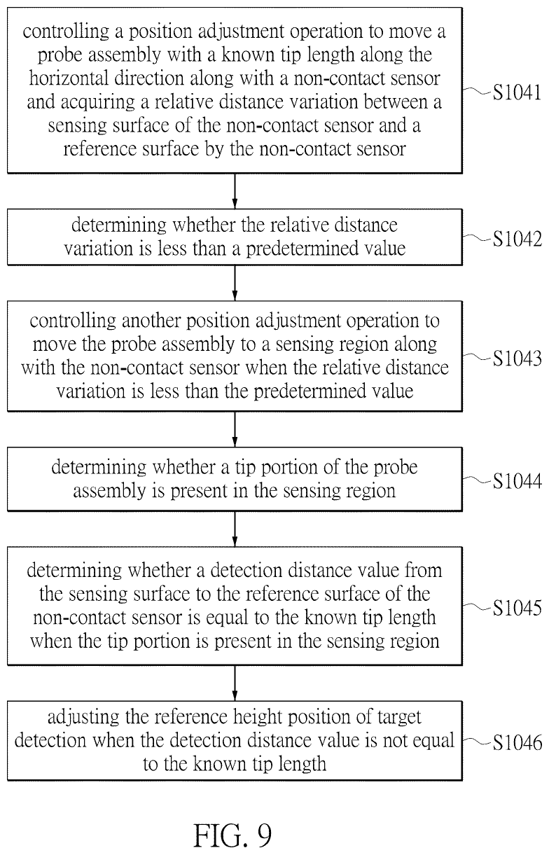

Reference is made to FIG. 9. In step S104, the pre-calibration operation includes: step S1041, controlling a position adjustment operation to move a probe assembly with a known tip length along the horizontal direction along with a non-contact sensor and acquiring a relative distance variation between a sensing surface of the non-contact sensor and a reference surface by the non-contact sensor; step S1042, determining whether the relative distance variation is less than a predetermined value; step S1043, controlling another position adjustment operation to move the probe assembly to a sensing region along with the non-contact sensor when the relative distance variation is less than the predetermined value; step S1044, determining whether a tip portion of the probe assembly is present in the sensing region; step S1045, determining whether a detection distance value from the sensing surface to the reference surface of the non-contact sensor is equal to the known tip length when the tip portion is present in the sensing region; and step S1046, adjusting the reference height position of target detection when the detection distance value is not equal to the known tip length.

Reference is made to FIG. 1 to FIG. 4A. Step S1041 and step S1042 are executed to measure the levelness of the reference surface 110. Specifically, in step S1041, a horizontal movement (e.g., a movement in the X or Y direction) of the probe assembly 2 can be caused by the position adjusting mechanism 12, and the non-contact sensor 23 is used to detect a distance from the sensing surface 230 to the reference surface 110 at any position during the horizontal movement. Accordingly, the relative distance variation between any two positions can be acquired and compared with the predetermined value. In step S1042, if the relative distance variation between any two positions on the reference surface 110 is stably less than the predetermined value (e.g., 5 μm), the reference surface 110 is considered horizontal. Step S1041 and step S1042 can be repeated if necessary. In practice, the levelness of the reference surface 110 can be adjusted by tightening or loosening fasteners such as screws on the calibration platform 111.

The pre-calibration operation proceeds from step S1042 to step S1043 when the relative distance variation between any two positions is stably less than the predetermined value. In step S1043, a downward movement of the probe assembly 2 to the sensing region 13R can be caused by the position adjusting mechanism 12. In step S1044, the target detection module 13 is used to determine where the tip portion 221 is in the sensing region 13R. In step S1045, when the tip portion 221 is detected as being present in the sensing region 13R, the non-contact sensor 23 is used to detect a distance from the sensing surface 230 to the reference surface 110. Accordingly, the detection distance value from the sensing surface 230 to the reference surface 110 can be acquired and compared with the known tip length. In step S1046, if the detection distance value is not equal to the known tip length, the reference height position of target detection is adjusted until the detection distance value of the non-contact sensor 23 is equal to the height difference. For example, the target detection module 13 includes a light adjusting component 133 with a light-permeable window 133W, and the light-permeable window 133W can be adjusted for adjusting a height of the light-permeable window 133W.

The relevant technical details mentioned in the first embodiment are still valid in the present embodiment and will not be repeated here for the sake of brevity.

### Third Embodiment

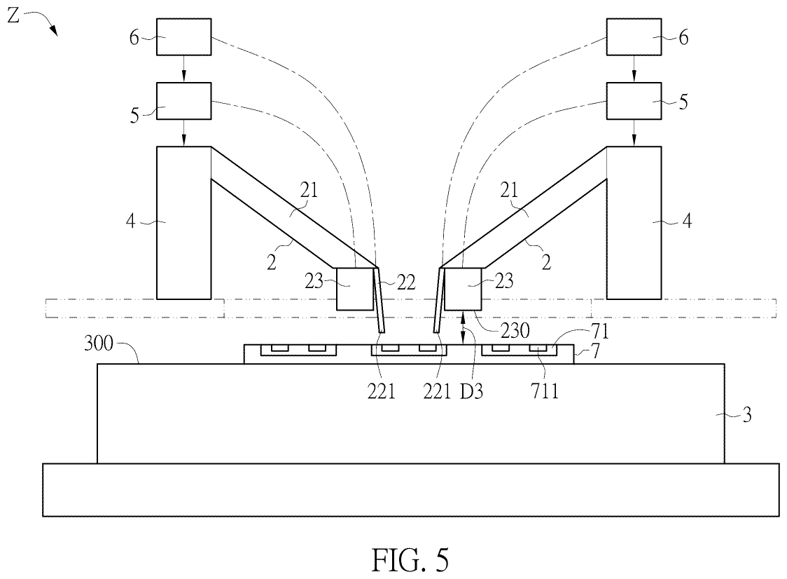

Referring to FIG. 5, a third embodiment of the present disclosure provides a probe system Z for testing an unpackaged semiconductor device, thereby producing a tested semiconductor device. The probe system Z mainly includes the tip length calibration device 1 as described in the first embodiment, a probe assembly 2, a chuck 3, and a motorized positioner 4.

In the third embodiment, the chuck 3 has a support surface 300 to support a substrate 7 that includes one or more devices under test (DUTs) 71. The probe assembly 2 is configured to test at least one of the one or more DUTs 71. The tip length calibration device 1 is configured to perform a tip length calibration operation on the probe assembly 2. Accordingly, a calibrated tip length (i.e., a fiber-to-sensor distance) of the probe assembly 2 can be acquired without direct contact with an object such as a calibration chuck, thereby preventing a tip portion 221 of the probe assembly 2 from being damaged. The motorized positioner 4 is configured to position the probe assembly 2 relative to the substrate 7.

In practice, the probe assembly 2 includes a retaining component 21, a probe 22, and a non-contact sensor 23. The retaining component 21 is mounted on and operatively connected to the motorized positioner 4. The probe 22 and the non-contact sensor 23 are retained on the retaining component 21, and a tip portion 221 of the probe 22 extends beyond a plane where a sensing surface 230 of the non-contact sensor 23 is located. The probe 22 is configured to provide a test signal to at least one of the one or more DUTs 71 or receive a resultant signal from at least one of the one or more DUTs 71. The non-contact sensor 23 is configured to detect a distance D3 from the substrate 7 to the sensing surface 230. In some examples, the probe 22 is an optical fiber, and each of the DUTs 71 includes at least one optical coupler 711.

In practice, the probe system Z can further include a signal generation and analysis device 5 and a controller 6. The signal generation and analysis device 5 is configured to generate the test signal and analyze the resultant signal. The controller 6 is configured to control the operation of the chuck 3, the motorized positioner 4, or the signal generation and analysis device 5. The signal generation and analysis device 5, when present, may be adapted, configured, designed, and/or constructed to provide a test signal to DUT via a tip portion 221 of probe assembly 2 and/or to receive a resultant signal from the DUT via the tip portion 221. Examples of the test signal include an electric test signal, an optical test signal, and/or an electromagnetic test signal. Examples of the resultant signal include an electric resultant signal, an optical resultant signal, and/or an electromagnetic resultant signal. Examples of signal generation and analysis device 5 include a signal generator, an electric signal generator, an optical signal generator, a signal transmitter, an electric signal transmitter, an optical signal transmitter, a signal receiver, an electric signal receiver, an optical signal receiver, a signal analyzer, an electric signal analyzer, and/or an optical signal analyzer.

The relevant technical details mentioned in the above embodiments are still valid in the present embodiment and will not be repeated here for the sake of brevity.

### Fourth Embodiment

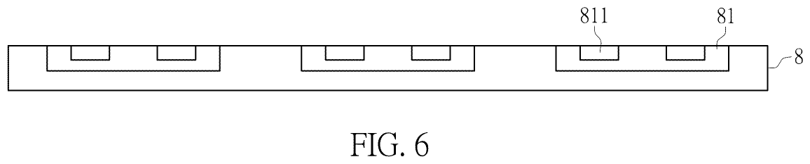

Referring to FIG. 5 and FIG. 6, a fourth embodiment of the present disclosure provides a tested semiconductor device, which includes an unpackaged semiconductor device 8. The unpackaged semiconductor device 8 includes one or more DUTs 81 with at least one optical coupler 811 to be interfaced with a probe assembly 2 in a probe system Z as described in the third embodiment.

The relevant technical details mentioned in the above embodiments are still valid in the present embodiment and will not be repeated here for the sake of brevity.

### Fifth Embodiment

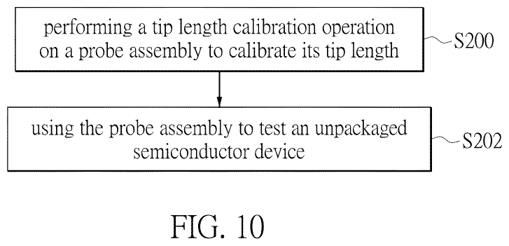

Referring to FIG. 10, a fifth embodiment of the present disclosure further provides a method for testing an unpackaged semiconductor device that is designed for use in an operational environment is further provided. The method can be applied to the production of a tested semiconductor device.

As shown in FIG. 10, the method includes: step S200, performing a tip length calibration operation on a probe assembly to calibrate its tip length; and step S202, using the probe assembly to test an unpackaged semiconductor device.

In step S202, the probe assembly can allow a connection to communicate test information with the unpackaged semiconductor device. Specifically, the probe assembly includes an optical fiber with a calibrated tip length to interface with at least one optical coupler of one or more DUTs of the unpackaged semiconductor device. Accordingly, the optical fiber can transmit optical signals to the unpackaged semiconductor device and/or receive optical signals from the unpackaged semiconductor device.

The relevant technical details mentioned in the above embodiments are still valid in the present embodiment and will not be repeated here for the sake of brevity.

### Beneficial Effects of the Embodiments

In conclusion, the tip length calibration device provided by the present disclosure can be used to perform a tip length calibration operation on a probe assembly, so as to make the probe assembly have a calibrated tip length without direct contact with an object such as a calibration chuck. Therefore, a tip portion of the probe assembly can be prevented from being damaged. Furthermore, the tip length calibration device can save time and effort for tip length calibration.

Furthermore, the probe assembly that has undergone the tip length calibration operation can be used in a probe system for testing an unpackaged semiconductor device, thereby producing a tested semiconductor device.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A tip length calibration device of a probe assembly, comprising:
a base having a reference surface corresponding in position to a sensing surface of a non-contact sensor of the probe assembly;
a position adjusting mechanism disposed on the base; and
a target detection module disposed on the base and configured to determine whether a tip portion of the probe assembly is present in a sensing region next to the reference surface;
wherein the position adjusting mechanism is configured to move the probe assembly toward the base, so as to have the tip portion be present in the sensing region to acquire a tip length that is a vertical distance between a tip end of the tip portion and the sensing surface.

2. The tip length calibration device according to claim 1, wherein the position adjusting mechanism includes a first movement assembly that is connected to a retaining component of the probe assembly, so as to drive the probe assembly to move along a first direction perpendicular to the reference surface.

3. The tip length calibration device according to claim 2, wherein the position adjusting mechanism includes a mounting plate for mounting the retaining component on the first movement assembly.

4. The tip length calibration device according to claim 2, wherein the position adjusting mechanism includes a second movement assembly and a third movement assembly, the second movement assembly is disposed on the base, the third movement assembly is disposed on the second movement assembly, and the first movement assembly is disposed on the third movement assembly; wherein the second movement assembly is drivingly connected to the third movement assembly, so as to move the probe assembly along a second direction perpendicular to the first direction via the third movement assembly; and wherein the third movement assembly is drivingly connected to the first movement assembly, so as to move the probe assembly along a third direction perpendicular to the second direction via the first movement assembly.

5. The tip length calibration device according to claim 2, wherein the retaining component includes a first end portion, a second end portion, and a middle portion extending from the first end portion to the second end portion, and the first end portion is immovably fixed to mounting plate; wherein the probe assembly includes a probe that has the tip portion, and the probe and the non-contact sensor are retained on the second end portion, such that the tip portion extends beyond a plane where the sensing surface is located.

6. The tip length calibration device according to claim 1, wherein the target detection module includes a light emitter and a light receiver that are respectively located at two sides of the sensing region and opposite to each other, the light emitter is configured to emit a light beam to be detected, and the light receiver is configured to receive the light beam, so as to provide a detection value; wherein, when the tip portion blocks the light beam and results in a change in detection value, the tip portion is determined as being present in the sensing region, and a distance between the sensing surface and the reference surface measured by the non-contact sensor is the tip length.

7. The tip length calibration device according to claim 6, wherein the target detection module further includes a light adjusting component that is located on a transmission path of the light beam and configured to allow a plane where the light beam is located to be coplanar with the reference surface.

8. The tip length calibration device according to claim 7, wherein the light adjusting component includes a light-permeable window that corresponds in position to a light emitting surface of the light emitter; wherein the light adjusting component is configured for adjusting a height of the light-permeable window.

9. The tip length calibration device according to claim 8, wherein the base includes a calibration platform that is at least partially disposed between the light emitter and the light receiver and provided with the reference surface, and the light adjusting component is disposed between the light emitter and the calibration platform.

10. The tip length calibration device according to claim 6, wherein the target detection module includes an amplifier that is electrically connected to the light receiver, so as to receive a sensing signal from the light receiver and amplify the sensing signal to generate a readout signal corresponding to the detection value.

11. A method for performing a tip length calibration operation on a probe assembly of a probe system, comprising:
providing the tip length calibration device as claimed in claim 1;
mounting the probe assembly on the position adjusting mechanism;
controlling an operation of the position adjusting mechanism to move the probe assembly toward the base;
determining, by the target detection module, whether a tip portion of the probe assembly is present in the sensing region next to the reference surface;
terminating the operation of the position adjusting mechanism when the tip portion is present in the sensing region; and
acquiring, by a non-contact sensor of the probe assembly, a tip length that is a vertical distance between a tip end of the tip portion and the sensing surface.

12. The method according to claim 11, wherein, before the step of performing the calibration operation, the method further comprises performing a pre-calibration operation, which includes:
providing another probe assembly that includes another probe and another non-contact sensor, wherein the another probe has another tip portion with a known tip length;
controlling an operation of the position adjusting mechanism to move the another probe assembly along the horizontal direction and acquiring, by the another non-contact sensor, a relative distance variation between a sensing surface of the another non-contact sensor and the reference surface;
determining whether the relative distance variation is less than a predetermined value;
controlling another operation of the position adjusting mechanism to move the another probe assembly toward the base when the relative distance variation is less than the predetermined value;
determining, by the target detection module, whether the another tip portion is present in the sensing region; and
determining whether a detection value of the another non-contact sensor is equal to the known tip length when the another tip portion is present in the sensing region, and if not, adjusting a height position of a light-permeable window of the target detection module until the detection value of the another non-contact sensor is equal to the known tip length.

13. A probe system, comprising:
a chuck having a support surface to support a substrate, the substrate including a device under test (DUT);
a probe assembly configured to test the DUT;
the tip length calibration device as claimed in claim 1 configured to perform a tip length calibration operation on the probe assembly; and
a motorized positioner configured to position the probe assembly relative to the substrate.

14. The probe system according to claim 13, wherein the probe assembly includes:
a retaining component connected to the motorized positioner;
a probe retained on the retaining component to provide a test signal to the DUT or receive a resultant signal from the DUT, wherein the probe has a tip portion; and
a non-contact sensor retained on the retaining component to detect a distance from the substrate to the sensing surface, wherein the non-contact sensor has a sensing surface, and the tip portion extends beyond a plane where the sensing surface is located.

15. The probe system according to claim 14, wherein the probe is an optical fiber.

16. A tested semiconductor device, comprising an unpackaged semiconductor device having at least one optical coupler configured to be interfaced with the probe assembly in the probe system as claimed in claim 13.

17. A method for testing an unpackaged semiconductor device, comprising:
using the tip length calibration device as claimed in claim 1 to perform a tip length calibration operation on a probe assembly, so as to acquire a calibrated tip length of the probe assembly; and
using the probe assembly to test an unpackaged semiconductor device, wherein the probe assembly includes an optical fiber to transmit optical signals to the unpackaged semiconductor device and/or receive optical signals from the unpackaged semiconductor device.

18. The method according to claim 17, wherein, in the step of using the probe assembly to test the unpackaged semiconductor device, the probe assembly includes an optical fiber with the calibrated tip length to interface with at least one optical coupler of one or more DUTs of the unpackaged semiconductor device.

19. A method for producing a tested semiconductor device, comprising:
using the tip length calibration device as claimed in claim 1 to perform a tip length calibration operation on a probe assembly, so as to acquire a calibrated tip length of the probe assembly; and
using the probe assembly to test an unpackaged semiconductor device, wherein the probe assembly includes an optical fiber to transmit optical signals to the unpackaged semiconductor device and/or receive optical signals from the unpackaged semiconductor device.

20. The method according to claim 19, wherein, in the step of using the probe assembly to test the unpackaged semiconductor device, the probe assembly includes an optical fiber with the calibrated tip length to interface with at least one optical coupler of one or more DUTs of the unpackaged semiconductor device.
